(19) United States
(12) Patent Application Publication
(10) Pub. No.: US 2025/0159919 A1
(43) Pub. Date: May 15, 2025

(54) TRANSISTOR

(71) Applicant: Japan Display Inc., Tokyo (JP)

(72) Inventor: Masumi NISHIMURA, Minato-ku (JP)

(73) Assignee: Japan Display Inc., Tokyo (JP)

(21) Appl. No.: 19/021,571

(22) Filed: Jan. 15, 2025

Related U.S. Application Data
(63) Continuation of application No. PCT/JP2023/020437, filed on Jun. 1, 2023.

(30) Foreign Application Priority Data
Aug. 3, 2022 (JP) 2022-124256

(51) Int. Cl. H10D 30/47; H10D 62/85

(52) U.S. Cl. CPC H10D 30/471; H10D 62/8503

(57) ABSTRACT

A transistor includes an amorphous substrate, a first buffer layer over the amorphous substrate, a first nitride semiconductor layer in an island-shaped pattern over the first buffer layer, a second nitride semiconductor layer over the first nitride semiconductor layer so as to cover the first nitride semiconductor layer, and a gate electrode layer over the second nitride semiconductor layer so as to overlap the first nitride semiconductor layer.

### CROSS-REFERENCE TO RELATED APPLICATIONS

This application is a Continuation of International Patent Application No. PCT/JP2023/020437, filed on Jun. 1, 2023, which claims the benefit of priority to Japanese Patent Application No. 2022-124256, filed on Aug. 3, 2022, the entire contents of which are incorporated herein by reference.

### FIELD

An embodiment of the present invention relates to a transistor using a compound semiconductor, in particular, a high electron mobility transistor (HEMT).

### BACKGROUND

Gallium nitride (GaN) is a direct bandgap semiconductor with a large bandgap. Focusing on the properties of gallium nitride, gallium nitride has the characteristics of high saturated electron mobility and a high breakdown voltage. In recent years, a transistor for a high-frequency power device, that is, a HEMT has been developed by utilizing the characteristics of gallium nitride.

The HEMT has a heterojunction structure in which not only gallium nitride but also aluminum gallium nitride (AlGaN) is provided in contact with the gallium nitride. At the interface between the gallium nitride and the aluminum gallium nitride, charges are induced by the spontaneous polarization of the gallium nitride functioning as the semiconductor layer and the piezoelectric effect of the aluminum gallium nitride functioning as the polarization layer, so that a high-density two-dimensional electron gas (2DEG) is formed. Since the concentration of the two-dimensional electron gas in the HEMT is large and the saturated electron mobility is also high, high-speed operation in the HEMT is possible.

Gallium nitride in a HEMT is generally formed on a sapphire substrate at a high temperature of 800 degrees to 1000 degrees using MOCVD (Metal Organic Chemical Vapor Deposition) or HVPE (Hydride Vapor Phase Epitaxy).

### SUMMARY

A transistor according to an embodiment of the present invention includes an amorphous substrate, a first buffer layer over the amorphous substrate, a first nitride semiconductor layer in an island-shaped pattern over the first buffer layer, a second nitride semiconductor layer over the first nitride semiconductor layer so as to cover the first nitride semiconductor layer, and a gate electrode layer over the second nitride semiconductor layer so as to overlap the first nitride semiconductor layer.

### BRIEF DESCRIPTION OF DRAWINGS

FIG. 1 is a schematic cross-sectional view showing a configuration of a transistor according to an embodiment of the present invention.

FIG. 2 is a schematic cross-sectional view showing a configuration of a transistor according to an embodiment of the present invention.

FIG. 3 is a schematic cross-sectional view showing a configuration of a transistor according to an embodiment of the present invention.

FIG. 4 is a schematic cross-sectional view showing a configuration of a transistor according to an embodiment of the present invention.

FIG. 5 is a schematic cross-sectional view showing a configuration of a transistor according to an embodiment of the present invention.

### DESCRIPTION OF EMBODIMENTS

In general, although gallium nitride is deposited on a sapphire substrate at a high temperature, it is difficult to increase the area of the sapphire substrate, and therefore it is difficult to reduce manufacturing costs. Therefore, the technology has been developed in which a buffer layer (an alignment layer) controlling a c-axis orientation of gallium nitride is provided on an amorphous substrate such as a glass substrate that is capable of having a large-area and the gallium nitride is deposited by sputtering at a low temperature. However, there is a problem that a HEMT easily has a normally-on type (depression type) property.

In view of the above problems, an embodiment of the present invention can provide a transistor having a structure that suppresses a normally-on type property and has a high freedom in design.

Hereinafter, each of the embodiments of the present invention is described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification, although the phrase “on” or “over” or “under” or “below” is used for convenience of explanation, in principle, the direction from a substrate toward a structure is referred to as “on” or “over” with reference to a substrate in which the structure is formed. Conversely, the direction from the structure to the substrate is referred to as “under” or “below.” Therefore, in the expression of “a structure over a substrate,” one surface of the structure in the direction facing the substrate is the bottom surface of the structure and the other surface is the upper surface of the structure. In addition, the expression of “a structure over a substrate” only explains the vertical relationship between the substrate and the structure, and another member may be placed between the substrate and the structure. Furthermore, the term “on” or “over” or “under” or “below” means the order of stacked layers in the structure in which a plurality of layers is stacked, and may not be related to the position in which layers overlap in a plan view.

In the specification, terms such as “first,” “second,” or “third” attached to each configuration are convenient terms used to distinguish each component, and have no further meaning unless otherwise explained.

In the specification and the drawings, the same reference numerals may be used when multiple components are identical or similar in general, and reference numerals with a lower or upper case letter of the alphabet may be used when the multiple components are distinguished. Further, reference numerals with a hyphen and a natural number may be used when multiple portions of one component are distinguished.

The following embodiments can be combined with each other as long as there is no technical contradiction.

### First Embodiment

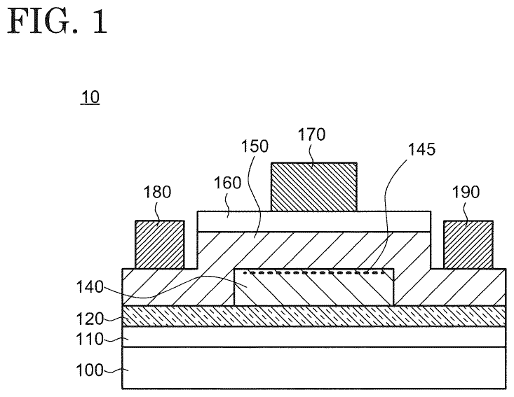

FIG. 1 is a schematic cross-sectional view showing a configuration of a transistor 10 according to an embodiment of the present invention.

As shown in FIG. 1, the transistor 10 includes an amorphous substrate 100, a base layer 110, a first buffer layer 120, a first nitride semiconductor layer 140, a second nitride semiconductor layer 150, a gate insulating layer 160, a gate electrode layer 170, a source electrode layer 180, and a drain electrode layer 190. The base layer 110 is provided on the amorphous substrate 100. The first buffer layer 120 is provided on the base layer 110. The first nitride semiconductor layer 140 has an island-shaped pattern and is provided on the first buffer layer 120. The second nitride semiconductor layer 150 is provided on the first nitride semiconductor layer 140 so as to cover the first nitride semiconductor layer 140. The gate insulating layer 160 is provided on the second nitride semiconductor layer 150 so as to overlap the first nitride semiconductor layer 140. The gate electrode layer 170 is provided on the gate insulating layer 160 so as to overlap the first nitride semiconductor layer 140. Each of the source electrode layer 180 and the drain electrode layer 190 are provided on the second nitride semiconductor layer 150 exposed from the gate insulating layer 160. Further, each of the source electrode layer 180 and the drain electrode layer 190 are in contact with the second nitride semiconductor layer 150.

The first nitride semiconductor layer 140 can be patterned by using photolithography. The first nitride semiconductor layer 140 is located between the source electrode layer 180 and the drain electrode layer 190 and does not overlap the source electrode layer 180 and the drain electrode layer 190.

The first nitride semiconductor layer 140 is in contact with the second nitride semiconductor layer 150. A first nitride semiconductor included in the first nitride semiconductor layer 140 is different from a second nitride semiconductor included in the second nitride semiconductor layer 150. Therefore, a heterojunction having a band discontinuity is formed at the interface between the first nitride semiconductor layer 140 and the second nitride semiconductor layer 150, and a two-dimensional electron gas (2DEG) 145 having high concentration and high mobility is generated in the vicinity of the junction interface due to spontaneous polarization and the piezoelectric effect. In other words, the first nitride semiconductor layer 140 and the second nitride semiconductor layer 150 can function as a channel layer and a polarization layer, respectively. That is, the transistor 10 is a so-called HEMT.

In addition, the transistor 10 may have a structure in which the base layer 110 or the gate insulating layer 160 is not provided. When the gate insulating layer 160 is not provided, the gate electrode layer 170 is in contact with the second nitride semiconductor layer 150 and functions as a so-called Schottky gate electrode.

The amorphous substrate 100 is a support substrate for the transistor 10. Although details are described later, the first nitride semiconductor layer 140 and the second nitride semiconductor layer 150 are formed by sputtering, so that the amorphous substrate 100 only needs to have heat resistance of, for example, about 600° C. Therefore, for example, an amorphous glass substrate can be used as the amorphous substrate 100. Further, a resin substrate such as a polyimide substrate, an acrylic substrate, a siloxane substrate, or a fluororesin substrate can also be used as the amorphous substrate 100. Such an amorphous glass substrate or resin substrate is a substrate that can be provided with a large area.

The base layer 110 can prevent the diffusion of impurities from the amorphous substrate 100 or impurities from the outside (e.g., moisture or sodium (Na)). For example, a silicon nitride (SiNₓ) film or the like can be used as the base layer 110. Further, a laminated film of a silicon oxide (SiOₓ) film and a silicon nitride (SiNₓ) film can be used as the base layer 110.

The first buffer layer 120 can control the crystal orientation of the first nitride semiconductor layer 140 formed by sputtering, and can improve the crystallinity of the first nitride semiconductor layer 140. Specifically, the first buffer layer 120 can control the crystallinity of the first nitride semiconductor layer 140 so that the first nitride semiconductor layer 140 has a c-axis orientation. For example, in the case where the first nitride semiconductor is gallium nitride, although the gallium nitride having a hexagonal close-packed structure grows in the c-axis direction so as to minimize surface energy, crystal growth of the gallium nitride with the c-axis orientation can be promoted by depositing the gallium nitride on the first buffer layer 120. A material having a hexagonal close-packed structure, a face-centered cubic structure, or a structure equivalent thereto can be used for the first buffer layer 120. Here, the structure equivalent to the hexagonal close-packed structure or the face-centered cubic structure includes a crystal structure in which the c-axis is not 90 degrees with respect to the a-axis and the b-axis. The first buffer layer 120 with the material having the hexagonal close-packed structure or the structure equivalent thereto can have an orientation in the (0001) direction, that is, in the c-axis direction with respect to the substrate 100 (hereinafter, referred to as the (0001) orientation of the hexagonal close-packed structure). Further, the first buffer layer 120 with the material having the face-centered cubic structure or the structure equivalent thereto can have an orientation in the (111) direction with respect to the substrate 100 (hereinafter, referred to as the (111) orientation of the face-centered cubic structure). When the first buffer layer 120 has the (0001) orientation of the hexagonal close-packed structure or the (111) orientation of the face-centered cubic structure, the crystal growth of the gallium nitride deposited on the first buffer layer 120 in the c-axis direction is promoted and the first semiconductor layer 140 has the c-axis orientation with high crystallinity.

The crystallinity of the first nitride semiconductor layer 140 on the first buffer layer 120 is affected by the surface state of the first buffer layer 120. Therefore, it is preferable that the first buffer layer 120 has a smooth surface with little unevenness. For example, the surface arithmetic mean roughness (Ra) of the first buffer layer 120 is preferably less than 2.3 nm. Further, the root mean square roughness (Rq) of the surface of the first buffer layer 120 is preferably less than 2.9 nm. When the surface roughness of the first buffer layer 120 satisfies the above conditions, the first nitride semiconductor layer 140 has the c-axis orientation with further high crystallinity. In addition, the thickness of the first buffer layer 120 is preferably greater than or equal to 50 nm.

A conductive material or an insulating material may be used for the first buffer layer 120. The first buffer layer 120 can be formed by any method (apparatus) such as sputtering or CVD.

Titanium (Ti), magnesium (Mg), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), or thorium (Th), or an alloy thereof can be used as the conductive material of the first buffer layer 120. Further, titanium nitride (TiNₓ), titanium oxide (TiOₓ), graphene, zinc oxide (ZnO), magnesium diboride (MgB₂), BiLaTiO, SrFeO, BiFeO, BaFeO, ZnFeO, or PMnN-PZT can be used as the conductive material of the first buffer layer 120. In particular, it is preferable to use titanium, graphene, or zinc oxide for the first buffer layer 120.

Further, silicon (Si), germanium (Ge), or an alloy thereof can be used as the conductive material of the first buffer layer 120. Although silicon and germanium are semiconductor materials, they have higher conductivity than insulating materials described later. Therefore, in the present specification, semiconductor materials such as silicon and germanium are included in the conductive material.

Aluminum nitride (AlN), aluminum oxide (Al₂O₃), silicon carbide (SIC), lithium niobate (LiNbO), BiLaTiO, SrFeO, SrFeO, BiFeO, BaFeO, ZnFeO, PMnN-PZT, or biological apatite (BAp) can be used as the insulating material of the first buffer layer 120. In particular, it is preferable to use aluminum nitride or silicon carbide for the first buffer layer 120.

As described above, the first nitride semiconductor layer 140 and the second nitride semiconductor layer 150 can function as a channel layer and a polarization layer of the HEMT, respectively. Although a compound semiconductor such as gallium nitride (GaN) and aluminum gallium nitride (AlGaN) is used for each of the first nitride semiconductor layer 140 and the second nitride semiconductor layer 150, the material of each of the first nitride semiconductor layer 140 and the second nitride semiconductor layer 150 is not limited thereto. For example, indium nitride (InN), aluminum indium nitride (AlInN), indium gallium nitride (InGaN), or aluminum indium gallium nitride (AlInGaN) can also be used for each of the first nitride semiconductor layer 140 and the second nitride semiconductor layer 150.

Since the first nitride semiconductor layer 140 is formed on the first buffer layer 120, the first nitride semiconductor layer 140 has the c-axis orientation with high crystallinity. Further, since the second nitride semiconductor layer 150 is formed on the first nitride semiconductor layer 140 having the c-axis orientation with high crystallinity, the second nitride semiconductor layer 150 also has a c-axis orientation with high crystallinity.

Here, a deposition of gallium nitride using sputtering is described as an example of forming the first nitride semiconductor layer 140.

The amorphous substrate 100 is placed facing a gallium nitride target in a vacuum chamber. It is preferable that the composition ratio of gallium nitride in the gallium nitride target is greater than or equal to 0.7 and less than or equal to 2 of gallium relative to nitrogen. Further, nitrogen can also be supplied to the vacuum chamber as a gas other than a sputtering gas (such as argon (Ar) or krypton (Kr)). In that case, it is preferable that the composition ratio of gallium nitride in the gallium nitride target is more gallium than nitrogen. For example, nitrogen can be supplied using a nitrogen radical source. The sputtering power supply source may be either a DC power supply source, an RF power supply source, or a pulsed DC power supply source.

The amorphous substrate 100 in the vacuum chamber may be heated. For example, the amorphous substrate 100 can be heated at a temperature higher than or equal to room temperature and lower than 600° C., preferably higher than or equal to 100° C. and lower than or equal to 400° C. This temperature can be applied to an amorphous glass substrate having low heat resistance. Further, this temperature is lower than the deposition temperature in MOCVD or HVPE.

After the vacuum chamber is sufficiently evacuated, the sputtering gas is supplied to the vacuum chamber. Further, a voltage is applied between the amorphous substrate 100 and the gallium nitride target at a predetermined pressure to generate a plasma and the gallium nitride film is deposited.

Although the deposition method of the gallium nitride by sputtering is described, the configurations or conditions of sputtering can be changed as appropriate. In addition, aluminum gallium nitride can be deposited using an aluminum gallium nitride target instead of the gallium nitride target.

Silicon oxide (SiOₓ), aluminum oxide (AlOₓ), hafnium oxide (HfOₓ), lanthanum oxide (LaOₓ), silicon nitride (SiNₓ), aluminum nitride (AlNₓ), or the like can be used for the gate insulating layer 160. The gate insulating layer 160 may be a single film or a laminated film.

A metal such as aluminum (Al), titanium (Ti), platinum (Pt), nickel (Ni), tantalum (Ta), or gold (Au), or alloys thereof can be used for the gate electrode layer 170. The gate electrode layer 170 may be a single film or a laminated film.

A metal such as aluminum (AI), titanium (Ti), platinum (Pt), nickel (Ni), tantalum (Ta), or gold (Au), or alloys thereof can be used for each of the source electrode layer 180 and the drain electrode layer 190. Each of the source electrode layer 180 and the drain electrode layer 190 may be a single film or a laminated film.

In the transistor 10 according to the present embodiment, the first nitride semiconductor layer 140 has the island-shaped pattern and does not overlap the source electrode layer 180 and the drain electrode layer 190. Therefore, the 2DEG 145 generated by the heterojunction also does not overlap the source electrode layer 180 and the drain electrode layer 190. Therefore, since the leakage current between the 2DEG 145 formed in the first nitride semiconductor layer 140 and the source electrode layer 180 or the drain electrode layer 190 can be suppressed, the transistor 10 has a normally-off type (enhancement type) property. Further, since the first nitride semiconductor layer 140 is patterned, the first nitride semiconductor layer 140 can be formed at any position. That is, the transistor 10 has a structure with high freedom in design.

### Modification 1 of First Embodiment

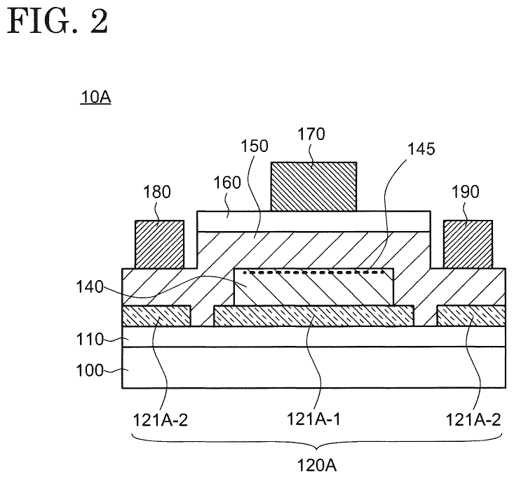

A modification of the transistor 10 is described with reference to FIG. 2. FIG. 2 is a schematic cross-sectional view showing a configuration of a transistor 10A according to an embodiment of the present invention. In the following description, when the configuration of the transistor 10A is similar to that of the transistor 10, the description of the configuration of the transistor 10A may be omitted.

As shown in FIG. 2, the transistor 10A includes the amorphous substrate 100, the base layer 110, a first buffer layer 120A, the first nitride semiconductor layer 140, the second nitride semiconductor layer 150, the gate insulating layer 160, the gate electrode layer 170, the source electrode layer 180, and the drain electrode layer 190. The first buffer layer 120A is patterned so that the base layer 110 is exposed. Further, the exposed base layer 110 is covered with the second nitride semiconductor layer 150. That is, the first buffer layer 120A includes a first region 121A-1 overlapping the first nitride semiconductor layer 140 and a second region 121A-2 not overlapping the first nitride semiconductor layer 140, and each end portion of the first region 121A-1 and the second region 121A-2 is covered with the second nitride semiconductor layer 150. The first region 121A-1 and the second region 121A-2 are separated from each other via the second nitride semiconductor layer 150 and are electrically insulated from each other via the second nitride semiconductor layer 150.

The first buffer layer 120A can be patterned using photolithography. The first region 121A-1 and the first nitride semiconductor layer 140 are located between the source electrode layer 180 and the drain electrode layer 190 and do not overlap the source electrode layer 180 and the drain electrode layer 190.

When the first buffer layer 120A includes a conductive material, the second region 121A-2 can be used for a lead wiring. In addition, the transistor 10A may have a configuration in which the second region 121A-2 is not provided.

In the transistor 10A according to the present modification 1, not only the first nitride semiconductor layer 140 but also the first region 121A-1 under the first nitride semiconductor layer 140 does not overlap the source electrode layer 180 and the drain electrode layer 190. Further, the first region 121A-1 and the second region 121A-2 are electrically insulated. Therefore, even when the first buffer layer 120A includes a conductive material, the transistor 10A has a normally-off type (enhancement type) property because the leakage current between the first buffer layer 120A (more specifically, the first region 121A-1) and the source electrode layer 180 or the drain electrode layer 190 can be suppressed. Furthermore, since the first buffer layer 120A is patterned, the transistor 10A has a normally-off type (enhancement type) property without depending on the material of the first buffer layer 120A. That is, the transistor 10A has a structure with high freedom in design.

### Modification 2 of First Embodiment

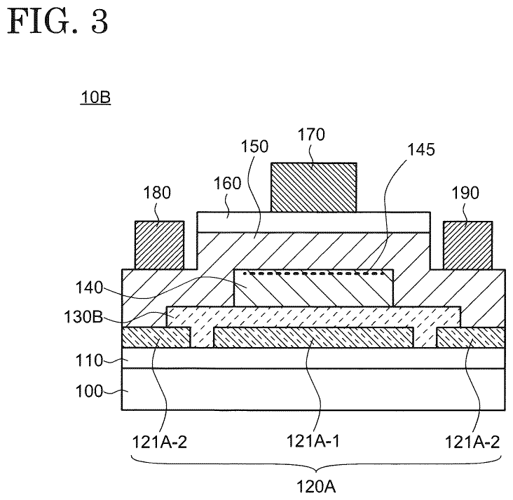

Another modification of the transistor 10 is described with reference to FIG. 3. FIG. 3 is a schematic cross-sectional view showing a configuration of a transistor 10B according to an embodiment of the present invention. In the following description, when the configuration of the transistor 10B is similar to that of the transistor 10 or the transistor 10A, the description of the configuration of the transistor 10B may be omitted.

As shown in FIG. 3, the transistor 10B includes the amorphous substrate 100, the base layer 110, the first buffer layer 120A, a second buffer layer 130B, the first nitride semiconductor layer 140, the second nitride semiconductor layer 150, the gate insulating layer 160, the gate electrode layer 170, the source electrode layer 180, and the drain electrode layer 190. The second buffer layer 130B is provided between the first buffer layer 120A and the first nitride semiconductor layer 140. The second buffer layer 130B is patterned so as to cover the first region 121A-1 and expose the second region 121A-2. The exposed second region 121A-2 is covered with the second nitride semiconductor layer 150. That is, each end portion of the first region 121A-1 and the second region 121A-2 are covered with the second buffer layer 130B.

The second buffer layer 130B has the same function as the first buffer layer 120A. That is, the second buffer layer 130B also controls the crystal orientation of the first nitride semiconductor layer 140 formed by sputtering, and can improve the crystallinity of the first nitride semiconductor layer 140. However, an insulating material is used for the second buffer layer 130B. Since the second buffer layer 130B includes the insulating material, the first region 121A-1 and the second region 121A-2 are separated from each other via the second buffer layer 130B and are electrically insulated from each other via the second buffer layer 130B.

The second buffer layer 130B can be patterned using photolithography. The second buffer layer 130B may or may not overlap the source electrode layer 180 or the drain electrode layer 190. In addition, the transistor 10B may have a structure in which the second buffer layer 130B is not patterned.

In the transistor 10B according to the present modification, the second buffer layer 130B includes the insulating material, and the first region 121A-1 and the second region 121A-2 are electrically insulated via the second buffer layer 130B. Therefore, even when the first buffer layer 120A includes a conductive material, the transistor 10B has a normally-off type (enhancement type) property because the leakage current between the first buffer layer 120A (more specifically, the first region 121A-1) and the source electrode layer 180 or the drain electrode layer 190 can be suppressed. Further, since the second buffer layer 130B is patterned so as to cover the first region 121A-1, the transistor 10B has a normally-off type (enhancement type) property without depending on the material of the first buffer layer 120A. That is, the transistor 10B has a structure with high freedom in design.

### Second Embodiment

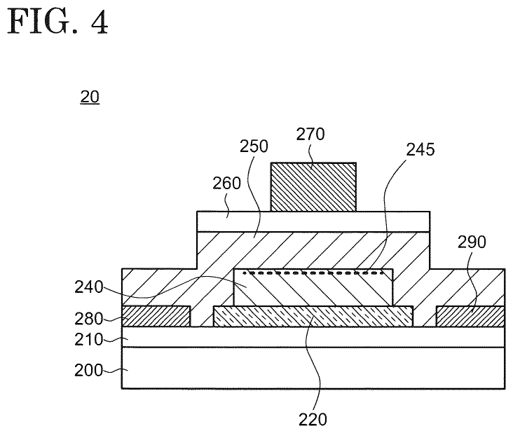

FIG. 4 is a schematic cross-sectional view showing a configuration of a transistor 20 according to an embodiment of the present invention. In the following description, when a configuration of the transistor 20 is similar to that of the transistor 10, the description of the configuration of the transistor 20 may be omitted.

As shown in FIG. 4, the transistor 20 includes an amorphous substrate 200, a base layer 210, a source electrode layer 280, a drain electrode layer 290, a first buffer layer 220, a first nitride semiconductor layer 240, a second nitride semiconductor layer 250, a gate insulating layer 260, and a gate electrode layer 270. The base layer 210 is provided on the amorphous substrate 200. The source electrode layer 280 and the drain electrode layer 290 are provided on the base layer 210. The first buffer layer 220 is provided on the base layer 210 so as to be located between the source electrode layer 280 and the drain electrode layer 290. The first nitride semiconductor layer 240 has an island-shaped pattern and is provided on the first buffer layer 220. The second nitride semiconductor layer 250 is provided on the source electrode layer 280, the drain electrode layer 290, and the first nitride semiconductor layer 240 so as to cover the source electrode layer 280, the drain electrode layer 290, and the first nitride semiconductor layer 240. Each of the source electrode layer 280 and the drain electrode layer 290 is in contact with the second nitride semiconductor layer 250. Further, an end portion of the first buffer layer 220 is covered with the second nitride semiconductor layer 250. The gate insulating layer 260 is provided on the second nitride semiconductor layer 250 so as to overlap the first nitride semiconductor layer 240. The gate electrode layer 270 is provided on the gate insulating layer 260 so as to overlap the first nitride semiconductor layer 240.

The transistor 20 is a so-called HEMT. That is, the first nitride semiconductor layer 240 and the second nitride semiconductor layer 250 function as a channel layer and a polarization layer, respectively, and a high-concentration and high-mobility two-dimensional electron gas (2DEG) 245 is generated in the vicinity of the junction interface between the first nitride semiconductor layer 240 and the second nitride semiconductor layer 250.

In the transistor 20, the first buffer layer 220 has the same function as the first buffer layer 120 described above. However, a conductive material is used for the first buffer layer 220. The first buffer layer 220 is provided in the same layer as the source electrode layer 280 and the drain electrode layer 290. That is, the first buffer layer 220, the source electrode layer 280, and the drain electrode layer 290 are formed by patterning the same conductive material. The first buffer layer 220, the source electrode layer 280, and the drain electrode layer 290 can be patterned using photolithography. In this way, since the source electrode layer 280 and the drain electrode layer 290 are formed by patterning the conductive material of the first buffer layer 220, the first buffer layer 220 does not overlap the source electrode layer 280 and the drain electrode layer 290.

In the transistor 20 according to the present embodiment, the first buffer layer 220 and the first nitride semiconductor layer 240 do not overlap the source electrode layer 280 and the drain electrode layer 290. Further, the first buffer layer 220 is electrically insulated from the source electrode layer 280 and the drain electrode layer 290 via the second nitride semiconductor layer 250. Therefore, since the leakage current between the first buffer layer 220 and the source electrode layer 280 or the drain electrode layer 290 can be suppressed, the transistor 20 has a normally-off type (enhancement type) property. Furthermore, since the source electrode layer 280 and the drain electrode layer 290 can be formed in the same process as the first buffer layer 220, the manufacturing tact time of the transistor 20 can be shortened and the manufacturing cost can be reduced. Moreover, the first buffer layer 220 does not overlap the source electrode layer 280 and the drain electrode layer 290 in the transistor 20. Therefore, since the first nitride semiconductor layer 240 can be formed in accordance with the pattern of the first buffer layer 220, the transistor 20 has a structure with high freedom in design.

### Modification of Second Embodiment

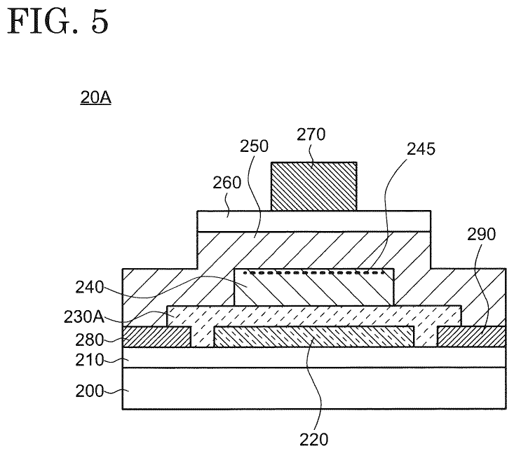

A modification of the transistor 20 is described with reference to FIG. 5.

FIG. 5 is a schematic cross-sectional view showing a configuration of a transistor 20A according to an embodiment of the present invention. In the following description, when the configuration of the transistor 20A is similar to that of the transistor 20, the description of the configuration of the transistor 20 may be omitted.

As shown in FIG. 5, the transistor 20A includes the amorphous substrate 200, the base layer 210, the source electrode layer 280, the drain electrode layer 290, the first buffer layer 220, a second buffer layer 230A, the first nitride semiconductor layer 240, the second nitride semiconductor layer 250, the gate insulating layer 260, and the gate electrode layer 270. The second buffer layer 230A is provided between the first buffer layer 220 and the first nitride semiconductor layer 240. The second buffer layer 230A covers the first buffer layer 220 and is patterned so that the source electrode layer 280 and the drain electrode layer 290 are exposed. Further, the exposed source electrode layer 280 and the exposed drain electrode layer 290 are covered with the second nitride semiconductor layer 250. That is, an end portion of each of the first buffer layer 220, the source electrode layer 280, and the drain electrode layer 290 are covered with the second buffer layer 230A.

The second buffer layer 230A has the same function as the first buffer layer 220. However, an insulating material is used for the second buffer layer 230A. Since the second buffer layer 230A includes the insulating material, the first buffer layer 220 and the source electrode layer 280 or the drain electrode layer 290 are separated from each other via the second buffer layer 230A and are electrically insulated from each other via the second buffer layer 230A.

The second buffer layer 230A can be patterned using photolithography. The second buffer layer 230A may or may not overlap the source electrode layer 280 or the drain electrode layer 290. In addition, the transistor 20A may have a structure in which the second buffer layer 230A is not patterned.

In the transistor 20A according to the present modification, the second buffer layer 230A includes an insulating material, and the first buffer layer 220 is electrically insulated from the source electrode layer 280 and the drain electrode layer 290 via the second buffer layer 230A. Therefore, since the leakage current between the first buffer layer 220 and the source electrode layer 280 or the drain electrode layer 290 can be suppressed, the transistor 20 has a normally-off type (enhancement type) property. Further, since the source electrode layer 280 and the drain electrode layer 290 can be formed in the same process as the first buffer layer 220, the manufacturing tact time of the transistor 20 can be shortened and the manufacturing cost can be reduced. Furthermore, since the second buffer layer 230A is patterned to cover the first buffer layer 220, the transistor 20A has a normally-off type (enhancement type) property without depending on the conductive material of the first buffer layer 220. That is, the transistor 20A has a structure with high freedom in design.

Each of the embodiments described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A transistor, comprising:
an amorphous substrate;
a first buffer layer over the amorphous substrate;
a first nitride semiconductor layer in an island-shaped pattern over the first buffer layer;
a second nitride semiconductor layer over the first nitride semiconductor layer so as to cover the first nitride semiconductor layer; and
a gate electrode layer over the second nitride semiconductor layer so as to overlap the first nitride semiconductor layer.

2. The transistor according to claim 1, wherein an end portion of the first buffer layer is covered with the second nitride semiconductor layer.

3. The transistor according to claim 1, further comprising a second buffer layer between the first buffer layer and the first nitride semiconductor layer,
wherein an end portion of the first buffer layer is covered with the second buffer layer.

4. The transistor according to claim 3,
wherein the first buffer layer comprises a conductive material, and
wherein the second buffer layer comprises an insulating material.

5. The transistor according to claim 1, further comprising a source electrode layer and a drain electrode layer over and in contact with the second nitride semiconductor layer.

6. The transistor according to claim 1, further comprising a source electrode layer and a drain electrode layer in a same layer as the first buffer layer.

7. The transistor according to claim 1, further comprising a gate insulating layer between the second nitride semiconductor layer and the gate electrode layer.

8. The transistor according to claim 1, further comprising a base layer between the amorphous substrate and the first buffer layer.

9. The transistor according to claim 1, wherein the first buffer layer comprises at least one selected from titanium, graphene, and zinc oxide.

10. The transistor according to claim 1, wherein the first buffer layer comprises at least one selected from silicon, germanium, and alloys thereof, and silicon carbide.

11. The transistor according to claim 1, wherein the amorphous substrate is an amorphous glass substrate.

12. The transistor according to claim 1,
wherein the first nitride semiconductor layer is in contact with the second nitride semiconductor layer, and
wherein a two-dimensional electron gas is generated in the vicinity of an interface between the first nitride semiconductor layer and the second nitride semiconductor layer.

13. The transistor according to claim 1, wherein the first nitride semiconductor layer comprises gallium nitride.
